(19) United States
(12) Patent Application Publication
(10) Pub. No.: US 2008/0020504 A1
(43) Pub. Date: Jan. 24, 2008

(54) Sensors for detecting NOx in a gas and methods for fabricating the same

(75) Inventors: Raju A. Raghurama, Bangalore (IN); Anilkumar Ramsesh, Bangalore (IN)

Correspondence Address: HONEYWELL INTERNATIONAL INC., 101 COLUMBIA ROAD, P O BOX 2245, MORRISTOWN, NJ, 07962-2245, US

(73) Assignee: Honeywell International, Inc.

(21) Appl. No.: 11/492,570

(22) Filed: Jul. 24, 2006

(51) Int. Cl. H01L 21/00

(52) U.S. Cl. 438/48

(57) ABSTRACT

Nitrogen oxide sensors and methods for fabricating them are provided. According to an exemplary embodiment of the present invention, the method comprises providing an electrically insulating substrate having a first surface and a second surface. Two electrodes are fabricated on the first surface of the substrate. Each of the electrodes has a first end configured to receive a current and a second end. A nanopowder of a barium tungstate comprising nanoparticles of substantially uniform particle size is synthesized. A film of the barium tungstate nanopowder is deposited overlying the first surface of the substrate and in electrical contact with the second ends of the electrodes. The film is sintered and a heater is fabricated on the second surface of the substrate.

### FIELD OF THE INVENTION

The present invention generally relates to nitrogen oxide sensors, and more particularly relates to nitrogen oxide sensors comprising a barium tungstate film and methods for making such sensors.

### BACKGROUND OF THE INVENTION

Nitrogen oxides, in particular NO and NO₂ (hereinafter “NOₓ”), are found in emissions from aircraft, automobiles and factories, and can cause damaging effects to human and animal bodies. NOₓ contributes to the production of acid rain, photochemical smog, and the depletion of the ozone layer. With an ever-increasing number of emission-producing vehicles, the amount of NOₓ produced also is increasing, causing deleterious effects on the global environment. Attempts to minimize environmental impacts have prompted efforts to reduce emissions from diesel and spark ignition engines. In particular, world-wide recommendations and laws for limiting NOₓ gas in emissions are becoming stricter for both industrial and domestic sources of pollution.

Such emissions standards have prompted attempts to develop on-board NOₓ sensors to monitor NOₓ in combustion exhausts. Various types of solid-state NOₓ sensors have been proposed based on semiconducting oxides, heterocontacts of semiconducting oxides, solid electrolytes, and the like. However, exhaust NOₓ sensors must meet various criteria to be practical and reliable. In particular, NOₓ sensors should be sensitive to both NO and NO₂ at high temperatures and should be operable at temperatures of 500° C. or more. The NOₓ sensors also should provide fast response, typically providing a response within 200 milliseconds or less. In addition, the sensors should have low cross-sensitivity to carbon monoxide and hydrocarbons. Moreover, the sensors should have low power requirements and be manufacturable at low cost. Few, if any, present-day NOₓ sensors meet these criteria.

Accordingly, it is desirable to provide a reliable NOₓ sensor that is sensitive to both NO and NO₂ at high temperatures and is operable at temperatures of approximately 500° C. or more. In addition, it is desirable to provide an NOₓ sensor that provides a fast response and exhibits low sensitivity to carbon monoxide and hydrocarbons. Furthermore, other desirable features and-characteristics of the present invention will become apparent from the subsequent detailed description of the invention and the appended claims, taken in conjunction with the accompanying drawings and this background of the invention.

### BRIEF SUMMARY OF THE INVENTION

In accordance with an exemplary embodiment of the present invention, a method for fabricating a sensor for detecting nitrogen oxides in a gas is provided. The method comprises providing an electrically insulating substrate having a first surface and a second surface. Two electrodes are fabricated on the first surface of the substrate. Each of the electrodes has a first end configured to receive a current and a second end. A heater is fabricated on the second surface of the substrate. A nanopowder of a barium tungstate comprising nanoparticles of substantially uniform particle size is synthesized. A film of the barium tungstate nanopowder is deposited overlying the first surface of the substrate and in electrical contact with the second ends of the electrodes.

In accordance with another exemplary embodiment of the invention, a method for fabricating nitrogen oxide sensor is provided. The method comprises providing an electrically insulating substrate having a first surface and a second surface and fabricating two electrodes on the first surface of the substrate. Each of the electrodes has a first end. A heater is fabricated on the second surface of the substrate. A barium tungstate nanopowder having nanoparticles of substantially uniform particle size in the range of about 3 nm to about 20 nm is synthesized and the nanopowder is dispersed in a medium. A barium tungstate film of the nanopowder/medium composition is formed overlying the first surface of the substrate and in electrical contact with the first ends of the electrodes. The film is sintered at a temperature in the range of about 750° C. to about 850° C. for about 15 minutes to about one hour.

In accordance with a further exemplary embodiment of the invention, an NO_{X} sensor is provided. The sensor comprises an electrically insulating substrate having a first surface and a second surface. Two electrodes are disposed overlying the first surface of the substrate. Each electrode has a first end configured to receive a current and a second end. A film of barium tungstate material is in electrical communication with the second ends of the two electrodes. A heater is disposed on the second surface of the substrate. The heater is configured to heat the barium tungstate material film to a temperature of at least about 500° C.

### BRIEF DESCRIPTION OF THE DRAWINGS

The present invention will hereinafter be described in conjunction with the following drawing figures, wherein like numerals denote like elements, and wherein:

FIG. 1 is a top view of a nitrogen oxide sensor in accordance with an exemplary embodiment of the present invention;

FIG. 2 is a bottom view of a nitrogen oxide sensor in accordance with an exemplary embodiment of the present invention;

FIG. 3 is a side view of a nitrogen oxide sensor in accordance with an exemplary embodiment of the present invention; and

FIG. 4 is a flow chart of a method for fabricating a nitrogen oxide sensor in accordance with an exemplary embodiment of the present invention.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

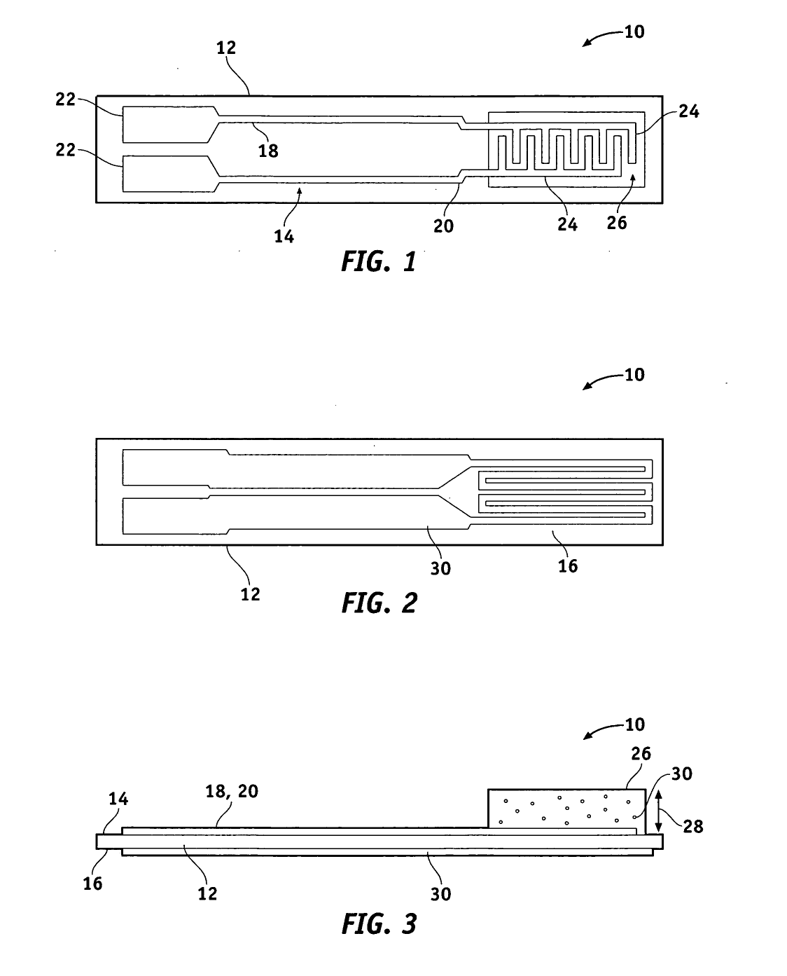

Referring to FIGS. 1-3, in accordance with an exemplary embodiment of the present invention, a sensor 10 for detecting nitrogen oxides, particularly nitrogen monoxide (NO) and nitrogen dioxide (NO₂) (hereinafter, collectively referred to as NOₓ), comprises a substrate 12 having a first surface 14 and a second surface 16. In an exemplary embodiment of the present invention, second surface 16 is parallel to first surface 14. The substrate may be formed from any suitable electrically-insulating and heat resistant material such as, for example, a ceramic. In a preferred embodiment of the invention, the substrate is formed of alumina (Al₂O₃). The substrate 12 may have any suitable size and shape. Preferably, the substrate 12 is an elongated plate having a thickness in the range of about 0.5 millimeters (mm) to about 1 mm, more preferably about 0.65 mm.

The sensor 10 also includes a first electrode 18 and a second electrode 20 disposed on the first surface 14 of the substrate 12. The electrodes may be formed of any suitable electrically conductive material. Examples of suitable materials from which the electrodes 18 and 20 may be formed include, but are not limited to, platinum (Pt), gold (Au), nickel (Ni), silver (Ag), conducting polymers, conducting metal oxides, and the like. In a preferred embodiment of the invention, the electrodes 18 and 20 comprise platinum. Each electrode 18 and 20 has a first end 22 and a second end 24. The first end 22 of each electrode is configured to receive a current. The second ends 24 may be configured in any suitable manner for conducting a current therebetween. In an exemplary embodiment of the invention, the second ends 24 of electrodes 18 and 20 are formed in a inter-digital structure, as illustrated in FIG. 1.

A film 26 of barium tungstate (Ba_{X}W_{Y}O_{Z}) material is disposed in electrical contact with the second ends 24 of the electrodes 18 and 20. In a preferred embodiment of the present invention, the film 26 is disposed overlying the electrodes 18 and 20, although it will be appreciated that the film 26 may be formed underlying the electrodes, the second ends 24 of electrodes 18 and 20 may be sandwiched between two films 26 of barium tungstate material, or the film 26 may be sandwiched between the two electrodes. The film 26 may be formed of any suitable barium tungstate material. In a preferred embodiment of the invention, the film is formed of BaWO₄, Ba₂WO₅, Ba₃W₂O₉, or a combination thereof. As illustrated in FIG. 3, the barium tungstate film 26 has a thickness, indicated by double headed arrow 28. In an exemplary embodiment of the invention, the thickness 28 is in the range of about 0.1 micrometers (μm) to about 5 μm, preferably in the range of about 1 μm to about 2 μm.

In an exemplary embodiment of the present invention, the barium tungstate film may be doped with a suitable dopant or dopants 30 to enhance the sensitivity and selectivity of the film 26 to particular gases. For example, noble metal particles such as platinum (Pt), palladium (Pd) and/or rhodium (Rh) particles can be impregnated in the barium tungstate film 26 and/or can be dispersed on the surface of the film.

Sensor 10 further comprises a heater 30 disposed on second surface 16 of the substrate 12. The heater 30 is comprised of any suitable heat-conducting material that is capable of heating barium tungstate film 26 to a temperature of at least about 450° C., preferably to a temperature of at least 500° C. In an exemplary embodiment of the invention, the heater 30 is an elongated conductor formed of platinum.

The sensor 10, as described above, has high sensitivity to NO₂ concentrations in a gas when it is heated to a temperature of about 450° C. to about 550° C., preferably about 500° C. The barium tungstate film is a p-conducting material and, when a constant electrical current is supplied through electrodes 18 and 20, the electrical resistance of the barium tungstate film decreases as the concentration of NO₂ in the gas increases. The change in voltage necessary to maintain a constant current corresponds to the NO₂ concentration and, accordingly, is measured to determine the NO₂ concentration. The sensor 10 also has nearly equal sensitivity to NO when operated at, preferably, 500° C. or higher. While not intending to be bound by any theory, this may be because the NO is oxidized catalytically to NO₂ on interacting with the barium tungstate film. While carbon monoxide (CO), carbon dioxide (CO₂), oxygen (O₂), hydrocarbons, and ammonia (NH₃) may be present in the gas, the barium tungstate film is not sensitive to these gases. The CO converts to (CO₂) upon interaction with the barium tungstate film. CO₂ and O₂ are neutral gases and are not detected by the sensor 10. Similarly, hydrocarbons will decompose into water vapor, CO₂, and possibly hydrogen. The hydrogen will be converted into water vapor at this temperature and will not be detected by the sensor 10. Ammonia will decompose into nitrogen and hydrogen and the hydrogen thus formed also will be converted into water vapor. As these two products are neutral in nature, the sensor may not detect them at a temperature within the above temperature range.

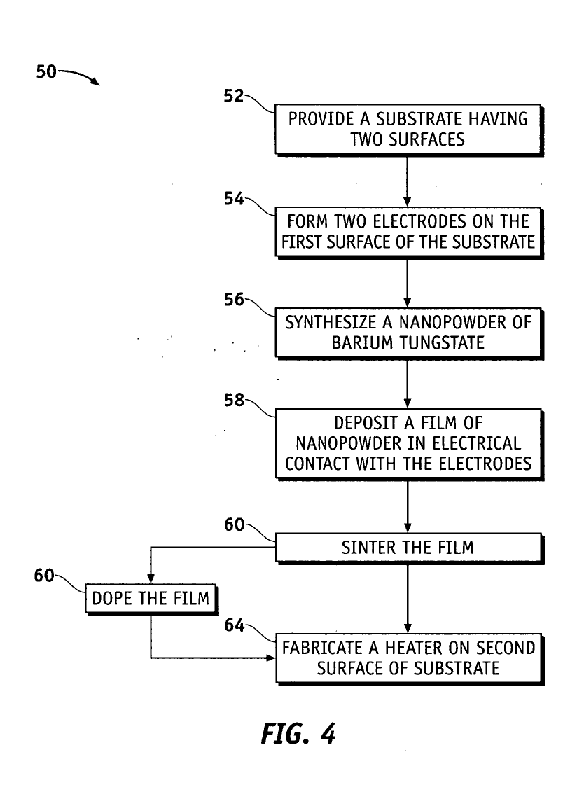

In accordance with an exemplary embodiment of the present invention, FIG. 4 illustrates a method 50 for fabricating a sensor for detecting nitrogen oxides, such as the sensor 10 of FIGS. 1-3. Various steps in the manufacture of sensor 10 are well known and so, in the interest of brevity, many conventional steps will only be mentioned briefly herein or will be omitted entirely without providing well known process details.

Referring to FIG. 4, various exemplary embodiments of a method 50 for fabricating a sensor for detecting nitrogen oxides in a gas now will be described. The method begins by providing an electrically-insulating and heat-resistant substrate plate having a first surface and a second surface (step 52). As described above, the substrate can be formed from any suitable electrically-insulating and heat-resistant substrate such as, for example, alumina. Two electrodes of an electrically conductive material are formed on the first surface of the substrate (step 54). The electrodes may be formed of any suitable electrically conductive material such as, for example, platinum (Pt), gold (Au), nickel (Ni), silver (Ag), conducting polymers, conducting metal oxides, and the like, by any suitable method. In an exemplary embodiment of the invention, the electrodes are formed by combining a platinum paste, ink, or paint with a suitable glass matrix and screen printing the platinum paste/glass matrix mixture in a desired configuration onto the substrate. The electrodes are then sintered, for example at about 1000° C. As the described above, the electrodes can have any suitable form or structure conducive to conducting a current therebetween. In an exemplary embodiment of the invention, the electrodes can have an elongated structure with inter-digital ends, as illustrated in FIG. 1.

Referring again to FIG. 4, a barium tungstate nanopowder is synthesized (step 56). Preferably, the nanopowder that is synthesized comprises BaWO₄, Ba₂WO₅, Ba₃W₂O₉, or any combination thereof. The sensitivity to NO_{X} of the barium tungstate film subsequently formed on the substrate, as discussed in more detail below, is determined in part by the particle size and porosity of the barium tungstate film. In turn, the particle size and porosity of the barium tungstate film are determined in part by the size of the nanoparticles that make up the barium tungstate nanopowder. In one embodiment of the invention, the nanopowder is formed from nanoparticles having an average size in the range of about 3 to about 20 nm.

The barium tungstate nanopowder may be synthesized using any suitable method that results in a nanopowder having nanoparticles in the range of about 3 to about 20 nm in size. In one exemplary embodiment of the invention, the barium tungstate nanopowder is synthesized using a chemical vapor synthesis method. In accordance with this method, appropriate portions of acetylacetonates of barium and tungsten are incorporated into an organic solution, such as, for example, a methanol solution to form a starting solution. For example, to prepare a BaWO₄ nanopowder, the starting solution may be formed from one mole of barium acetylacetonate and one mole of tungsten acetylacetonate. To prepare a Ba₂WO₅ nanopowder, the starting solution will be formed from two moles of barium acetylacetonate and one mole of tungsten acetylacetonate and to prepare a Ba3W2O₉ nanopowder, the starting solution will be formed from three moles of barium acetylacetonate and two moles of tungsten acetylacetonate. The starting solution is evaporated into a vapor and the vapor is passed into a chemical vapor synthesis chamber having halogen lamps therein and having cooled chamber walls. A gas, such as air and helium, is pumped into the chamber at a predetermined flow rate. The vapor decomposes upon entering the chamber and reacts with oxygen in the gas to form a barium tungstate nanocrystalline powder. The nanocrystalline powder is attracted to the cold chamber walls by a thermo-gravitational process and the particle size is seized due to this process. The size of the particles depends on the temperature of the chamber, which is maintained at a temperature in the range of about 150° C. to about 200° C., and the flow rate of the gas. The resulting nanoparticles of the nanopowder have a substantially spherical shape and are substantially uniform in size. In a preferred embodiment of the invention, the nanoparticles formed by the chemical vapor synthesis method have an average size in the range of about 3 to about 10 nm.

In another exemplary embodiment of the invention, the barium tungstate nanopowder may be synthesized by a sol-gel process. Sol-gel processes are well known and any suitable sol-gel process that results in a nanopowder having nanoparticles in the range of about 15 to about 20 nm in size may be used. In accordance with one exemplary embodiment of the present invention, suitable molar ratios of barium nitrate and tungsturic acid are incorporated into an aqueous solution. Citric acid, in a molar concentration twice that of the barium nitrate and tungsturic acid, is added to the solution along with double distilled water. The solution is heated, preferably to a temperature of about 80° C., and dilute ammonium hydroxide is added slowly while the solution is stirred well to cause a resulting precipitate to settle out of the solution. Additional ammonium hydroxide may be added to ensure that the precipitate dissolves fully. The liquid is dried by stirring continuously at 80° C., resulting in a substantially transparent gel. The gel is heated, preferably to a temperature of about 200° C., to obtain a xerogel, which is heated to about 400° C. to obtain the barium tungstate nanopowder. The resulting nanoparticles of the nanopowder have nearly uniform particle size. In a preferred embodiment of the invention, the nanoparticles formed by the above-described sol-gel method have an average size in the range of about 15 to about 20 nm.

Once formed, the barium tungstate nanopowder is deposited as a film onto the first surface of the substrate in electrical contact with the second ends of the electrodes (step 58). In one embodiment of the invention, the nanopowder may be dispersed in an alcohol medium, such as, for example, isopropyl alcohol. The nanopowder/medium composition is mixed with any suitable binder that does not alter the properties of the barium tungstate material, such as, for example, isopropyl alcohol. The nanopowder/medium mixture then may be deposited onto the substrate using a screen printing method. In another embodiment of the invention, the nanopowder can be dispersed in an organic liquid such as, for example, hexane and deposited on the substrate by spin coating or dip coating. It will be appreciated that any other suitable method for depositing the barium tungstate film on the substrate also may be used. In one exemplary embodiment of the present invention, the barium tungstate film is deposited overlying the second ends of the electrodes. In another exemplary embodiment, the barium tungstate film is deposited on the substrate before the electrodes are formed on the substrate (that is, before step 54). In a further exemplary embodiment, a barium tungstate film is deposited before the electrodes are formed on the substrate and is deposited overlying the second ends of the electrodes such that the electrodes are effectively “sandwiched” between two barium tungstate films.

The method in accordance with an exemplary embodiment of the present invention continues with the sintering of the nanopowder film (step 60). By regulating the sintering temperature and time, the grain size and the porosity of the barium tungstate film can be controlled. If the grain growth is too large, the porosity of the film is reduced and, hence the sensitivity of the film to NO_{X} is decreased. In an exemplary embodiment of the present invention, the barium tungstate film is sintered at a temperature range of about 750 to about 850° C., preferably at a temperature of about 800° C. In addition to regulating the particle size and the porosity of the barium tungstate film, sintering at such high temperatures causes the sensors to be operable at such high temperatures, preferably at temperatures of about 500° C. and higher. In another exemplary embodiment of the invention, the barium tungstate film is sintered for about 15 minutes to about one hour, preferably for about 30 minutes. While the nanopowder/medium mixture may be deposited to any suitable thickness, preferably the mixture is deposited so that, upon sintering, the barium tungstate film has a thickness in the range of about 0.1 micrometers (μm) to about 5 μm, preferably in the range of about 1 μm to about 2 μm.

In accordance with an exemplary embodiment of the invention, the barium tungstate film optionally may be doped with a suitable dopant or dopants to enhance the sensitivity and selectivity of the film to particular gases (step 62). For example, the barium tungstate film can be doped with noble metal particles such as platinum (Pt), palladium (Pd) and/or rhodium(Rh) particles to enhance the barium tungstate film's sensitivity to NO and NO₂ and reduce sensitivity to CO and O₂ gases. The dopants can be impregnated in the barium tungstate film by adding the particles to the mediums described above or otherwise can be dispersed on the surface of the film. In one exemplary embodiment, approximately 1 to 5% dopant may be added to the barium tungstate powder.

Method 50 further comprises the step of forming a heater on the second surface of the substrate (step 64). The heater may be formed of the same material as the electrodes formed on the first surface of the substrate or may be formed of any other suitable electrically conductive material such as, for example, platinum (Pt), gold (Au), silver (Ag), nickel (Ni), conducting polymers, conducting metal oxides, and the like, by any suitable method. In an exemplary embodiment of the invention, the heater is formed by combining a platinum paste with a suitable glass matrix and screen printing the platinum paste/glass matrix mixture in a desired form onto the substrate. The heater then is sintered, for example at about 1000° C. The heater can have any suitable form or structure conducive to heating the barium tungstate film to a temperature no less than about 450° C., preferably no less than about 500° C. It will be appreciated that, while the step 64 of forming a heater on the substrate is indicated as the last step of method 50, the step 64 of forming a heater may be performed as the first step of the method 50 or as any step therein.

Accordingly, NO_{X} sensors and methods for forming such sensors have been provided. The sensors are equally sensitive to NO and NO₂ gases in a test gas and are insensitive to CO, O₂, NH₃, and hydrocarbon gases. In addition, the sensors provide fast response and are operable at temperatures of approximately 500° C. and higher. While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for fabricating a sensor for detecting nitrogen oxides in a gas, the method comprising the steps of:
providing an electrically insulating substrate having a first surface and a second surface;
fabricating two electrodes on the first surface of the substrate, wherein each of the electrodes has a first end configured to receive a current and a second end;
fabricating a heater on the second surface of the substrate;
synthesizing a nanopowder of a barium tungstate, wherein the nanopowder comprises nanoparticles of substantially uniform particle size;
depositing a film of the barium tungstate nanopowder overlying the first surface of the substrate and in electrical contact with the second ends of the electrodes; and
sintering the film.

2. The method of claim 1, wherein the step of synthesizing a nanopowder of barium tungstate comprises the step of sintering a nanopowder of BaWO₄, Ba₂WO₅, Ba₃W₂O₉, or any combination thereof.

3. The method of claim 1, wherein the step of depositing a film of the nanopowder comprises the step of causing the film to be doped with a dopant.

4. The method of claim 3, wherein the step of causing the film to be doped with a dopant comprises the step of causing the film to be doped with platinum, palladium, rhodium, or a combination thereof.

5. The method of claim 1, wherein the step of synthesizing a nanopowder of barium tungstate comprises the step of synthesizing the nanopowder of barium tungstate using a chemical vapor synthesis method.

6. The method of claim 1, wherein the step of synthesizing a nanopowder of barium tungstate comprises the step of synthesizing the nanopowder of barium tungstate using a sol-gel method.

7. The method of claim 1, wherein the step of depositing a film of the nanopowder comprises the step of dispersing the barium tungstate nanopowder in an alcohol medium and screen printing the nanopowder/alcohol medium composition onto the first surface of the substrate and in electrical contact with the second ends of the electrodes.

8. The method of claim 1, wherein the step of depositing a film of the nanopowder comprises the step of dispersing the barium tungstate nanopowder in an organic medium and spin coating or dip coating the nanopowder/organic medium composition onto the first surface of the substrate and in electrical contact with the second ends of the electrodes.

9. The method of claim 1, wherein the step of synthesizing a nanopowder of a barium tungstate, wherein said nanopowder comprises nanoparticles of substantially uniform particle size, comprises the step of synthesizing a nanopowder having nanoparticles with a size in the range of about 3 nm to about 20 nm.

10. The method of claim 1, wherein the step of sintering the film comprises the step of sintering the film at a temperature in the range of about 750 to about 850° C.

11. The method of claim 10, wherein the step of sintering the film comprises the step of sintering the film at a temperature of about 800° C.

12. The method of claim 1, wherein the step of sintering the film comprises the step of sintering the film for about 15 minutes to about one hour.

13. The method of claim 12, wherein the step of sintering the film comprises the step of sintering the film for about one half hour.

14. A method for fabricating a nitrogen oxide sensor, the method comprising the steps of:
providing an electrically insulating substrate having a first surface and a second surface;
fabricating two electrodes on the first surface of the substrate, wherein each of the electrodes has a first end;
fabricating a heater on the second surface of the substrate;
synthesizing a nanopowder of a barium tungstate, wherein said nanopowder is synthesized such that the nanopowder has nanoparticles of substantially uniform particle size in the range of about 3 nm to about 20 nm;
dispersing the nanopowder in a medium;
forming a barium tungstate film of the nanopowder/medium composition overlying the first surface of the substrate and in electrical contact with the first ends of the electrodes; and
sintering the film at a temperature in the range of about 750° C. to about 850° C. for about 15 minutes to one hour.

15. The method of claim 14, wherein the step of synthesizing a nanopowder of barium tungstate comprises the step of sintering a nanopowder of BaWO₄, Ba₂WO₅, Ba₃W₂O₉, or any combination thereof.

16. The method of claim 14, further comprising the step of causing the barium tungstate film to be doped with a dopant, wherein the step of causing is performed after the step of synthesizing a nanopowder of a barium tungstate.

17. The method of claim 16, wherein the step of causing the barium tungstate film to be doped with a dopant comprises the step of causing the barium tungstate film to be doped with platinum, palladium, rhodium, or a combination thereof on the surface of the film.

18. An NO_{X} sensor comprising:
an electrically insulating substrate having a first surface and a second surface;
two electrodes disposed overlying the first surface of the substrate, wherein each electrode has a first end configured to receive a current and a second end;
a film of barium tungstate material in electrical communication with the second ends of the two electrodes; and
a heater disposed on the second surface of the substrate, wherein the heater is configured to heat the barium tungstate material film to a temperature of at least about 500° C.

19. The NO_{X} sensor of claim 18, wherein the film of barium tungstate material has a thickness in the range of about 0.1 micrometers (μm) to about 5 μm.

20. The NO_{X} sensor of claim 18, wherein the film of barium tungstate material comprises BaWO₄, Ba₂WO₅, Ba₃W₂O₉, or any combination thereof.
